(19) United States
(12) Patent Application Publication
(10) Pub. No.: US 2024/0258750 A1
(43) Pub. Date: Aug. 1, 2024

(54) Adapter device and method for measuring the signal power in a coaxial connection

(71) Applicant: SICK AG, Waldkirch (DE)

(72) Inventors: Florian PUDENZ, Waldkirch (DE); Björn SOCK, Waldkirch (DE)

(21) Appl. No.: 18/426,987

(22) Filed: Jan. 30, 2024

(30) Foreign Application Priority Data
Jan. 31, 2023 (EP) 23154344.8

(51) Int. Cl. H01R 13/66; G01R 31/28; G06K 7/10; H01Q 1/22; H01R 24/54

(52) U.S. Cl. CPC H01R 13/6683; G01R 31/2832; G06K 7/10316; H01Q 1/2225; H01R 24/542

(57) ABSTRACT

An adapter device for measuring the signal power in a coaxial connection from an RFID reading device to a second device is provided, wherein the adapter device has a first coaxial connector and a second coaxial connector for deploying the adapter device in the coaxial connection and a measuring unit that is configured to determine the signal power of a signal propagating from the first coaxial connector to the second coaxial connector and/or vice versa, In this respect, the first coaxial connector and the second coaxial connector are releasable so that the adapter device can selectively be deployed in the coaxial connection or can be removed therefrom.

The invention relates to an adapter device and to a method for measuring the signal power in a coaxial connection from an RFID reading device to a second device, in particular an antenna, respectively.

RFID readers serve the identification of objects and products and are used inter alia to automate logistical movements. RFID transponders fastened to the products are read at an identification point, above all on a change of the owner of the product or on a change of the transport means, and information is optionally written back into the transponder. This results in fast and traceable logistical movements. The detected information is used to control the forwarding and sorting of goods and products. Important applications for automatic identification are logistics distribution centers, for instance of parcel shippers, or the baggage check-in at airports.

RFID transponders can basically be active, that is have their own energy supply and generate electromagnetic radiation independently. In practice, however, these transponders are less suitable for logistics because the unit prices of such transponders cannot reach the low level required for the mass market due to the energy supply. Passive transponders without their own energy supply are therefore usually used. In both cases, the transponder is excited to radiate the stored information by electromagnetic radiation of the reading device, with passive transponders taking the required energy from the transmission energy of the reading system. In the established ultra high frequency standard ISO 18000-6, passive transponders are read using the backscatter process.

RFID devices use internal or external antennas, with an external antenna as a rule being subsequently connected. In this respect, coaxial connections and coaxial cables are used whose properties are not known. There are different reasons for this: The properties may not be measured or specified from the start. Even with a preconfigured coaxial cable, deviations from the specification given ex works may arise due to effects such as mechanical damage on the installation or aging in operation. If, however, the transmission losses or values of the cable damping are not known, a lossless coaxial connection must be assumed as a precaution and the transmission power may therefore be set to at most the maximum permitted value. However, this does not make use of the allowed transmission power since the really achieved transmission power becomes lower due to the transmission losses, which in turn reduces the maximum reading range.

An antenna for a write/read device for RFID arrangements is known from EP 2 712 021 A1. The antenna is equipped with a data store with type information and/or property information and furthermore has a measuring device for determining at least one value of the field strength or power of a radio frequency signal fed into the antenna. The functionality is thus tied to particular antennas; it is not possible to use any desired antennas. In an embodiment, the content of the data store can be transmitted bitwise by means of a clocked short circuit of the antenna cable. During the periods in which a short circuit is produced, a correspondingly equipped write/read device can measure further cable parameters such as cable damping or reflection losses occurring at the antenna. In addition to a special antenna, a special write/read device is then also required for this purpose that brings along this measurement functionality.

An RFID reading device is described in EP 2 442 255 A1 whose antenna has a data carrier in which the antenna parameters are stored for a facilitated installation of the RFID reading device, with the data carrier being able to be an RFID transponder.

U.S. Pat. No. 10,181,656 B2 deals with an antenna unit that has an antenna and a coaxial connector. The coaxial connector has an internal memory that makes it possible to identify the connected antenna and that is supplied via the coaxial cable. Transmission losses of the antenna cable are not discussed and a measurement of parameters is not provided overall.

U.S. Pat. No. 10,339,346 B2 discloses an antenna having an integrated RFID IC that makes it possible to select a respective one of a plurality of antenna elements by means of radio frequency switches. A resonant frequency or a directivity of the antenna can thereby be adapted, for example. Neither transmission losses of the antenna cable nor generally a possibility of measuring properties are again addressed.

It is therefore the object of the invention to further improve the setting up of an RFID reading device.

This object is satisfied by an adapter device and by a method for measuring the signal power in a coaxial connection from an RFID reading device to a second device, in particular an antenna, in accordance with the respective independent claim. An RFID reading device, in brief an RFID reader, is typically, despite the shortened name, also able to write data to an RFID transponder. The adapter device is deployed in accordance with the intended purpose in a coaxial connection between the reading device and the second device in the coaxial connection by which the second device is connected to the RFID reading device. The second device is preferably an antenna and in the following the antenna is consistently used as representative for the second device. The coaxial connection is preferably a coaxial cable or an antenna cable, with alternatively a direct connection of the second device to the RFID reading device being conceivable. The coaxial connection transmits the signal whose signal power should be measured, preferably a radio frequency signal or RFID signal. The measurement of the signal power is preferably only an intermediate result; the actual aim is then a derived value, in particular the determination of the transmission loss or the damping of the coaxial connection.

The adapter device has a first coaxial connector and a second coaxial connector for use in the coaxial connection. In the deployed state, the adapter device is accordingly connected to the coaxial connection at both sides by the first coaxial connector and the second coaxial connector so that the coaxial connection now runs through the adapter device. A measuring unit determines the signal power running to and/or back of the signal propagated by the adapter device.

The invention starts from the basic idea of selectively subsequently deploying the adapter device in the coaxial connection or removing it from there again. The first coaxial connector and the second coaxial connector are designed as releasable for this purpose. For example a plug-in connection is suitable that can be secured by a screw connection or the like such as a TNC or R-TNC connector that is widespread for antennas and coaxial cables.

The invention has the advantage that the functionality of the adapter device is added to an existing system of an RFID reading device and to a second device connected thereto and the invention is thus accessible for any desired RFID reading devices and second devices. A separate measurement functionality in an RFID reading device or in an antenna connected thereto is required. Parameters of the coaxial connection can be determined in a simple manner, in particular the damping or the transmission losses. Statements on the quality of the second device are possible in the same way. In operation of the RFID reading device, the transmission power can be suitably set while taking account of transmission losses in the coaxial connection. Maximum permitted signal levels can thereby be exhausted and reliably observed in so doing to optimize the reading range. In the case of cascaded coaxial connections, measurements can take place at different points in the signal path to localize defective components. The adapter device can be successively deployed in different coaxial connections to thus evaluate different systems of RFID reading devices and second devices. The adapter device is required, for example, only during the installation or in a servicing. If the adapter device remains deployed, on the other hand, deteriorations can be recognized at an early time by a regular measurement (predictive maintenance).

The measurement unit is preferably configured to determine a maximum value of the signal power. Contrary to an average formation, for example, statements are thus made on the observation of a permitted maximum power independently of modulations of the signal during the measurement of the signal power.

The adapter device preferably has an energy supply unit by which the adapter device supplies itself from the signal that propagates on the coaxial connection. A battery or the like is thus not required. The energy supply unit can be based on phantom feeding or remote feeding and can have a bias T for this, for example. An alternative comprises charging an energy store, for example a capacitor, from the signal and to use a rectifier or a charge pump for this, for example, so that no phantom voltage has to be provided.

The adapter device preferably has a memory in which the measuring unit stores a measured value for the signal power. At least the last measured signal power is thus available for reading. A plurality of measured values or of parameters derived therefrom can also be stored, in particular to thus achieve more exact results from a plurality of measurements.

The memory is preferably readable by means of an RFID protocol and in particular has an RFID transponder circuit. The RFID reading device thereby does not require any special communication or data interface for the adapter device since the RFID protocol anyway understands an RFID reading device. An example for the RFID protocol is the standardized EPC Gen² protocol or a protocol corresponding to the closely related standard ISO 18000-6 named in the introduction. For this purpose, the memory can be based on the same inexpensively present technology such as an RFID transponder, i.e. have a corresponding RFID transponder circuit.

The measuring unit is preferably configured to check the memory for a start signal stored there and to carry out a measurement of the signal power on the presence of a start signal. The communication between the adapter device and the RFID reading device is thus exceptionally simple via accesses to the memory that do not require any more complex coordination or synchronization. The RFID reading device reports its requirement for a measurement of the signal level over the start signal. The measuring unit determines this requirement with reference to the start signal, carries out the measurement, and stores the measured result in the memory again for an access of the RFID reading devices at any desired later point in time.

In a preferred further development, an RFID reading device is provided that has a second device, in particular an antenna, and a coaxial connection to the second device as well as at least one first adapter device in accordance with the invention whose first coaxial connector and second coaxial connector is deployed in the coaxial connection, wherein the first adapter device is arranged at an end of the section of the coaxial connection to be measured remote with respect to the RFID reading device. Different constellations are conceivable where the first coaxial connector and the second coaxial connector are connected. The first coaxial connector can be directly connected to the RFID reading device or to an end of a coaxial cable of the coaxial connection. The second coaxial connector can accordingly be directly connected to the second device or to an end of a coaxial cable. If the coaxial cable has a plurality of part sections, the end of the coaxial cable can equally mean an end of a part section. As a yet further alternative, the RFID reading device can originally be directly connected to the second device; in this case, the first adapter device then replaces the direct connection. The first adapter device forms the end of the section of the coaxial connection to be measured remote with respect to the RFID reading device.

The transmission power of the RFID reading device is preferably known in the RFID reading device and the RFID reading device is configured to determine a transmission loss of the coaxial connection from the known transmission power and a measured value of the first adapter device. In this embodiment, there is a certain prior knowledge of the signal power, namely how much of the signal is originally produced by the RFID reading device. The RFID reading device is preferably adapted such that this original signal power is actually fed into the coaxial connection or a corresponding initial loss is known. Only a comparison of the known original signal power with a corresponding measured value of the first adapter device is then required for the transmission loss of the coaxial connection, in strict terms of the section of the coaxial connection from the RFID reading devices to the first adapter device. If the transmission loss of the total coaxial connection is to be measured, the first adapter device is to be directly connected to the second device as remote from the RFID reading device as possible.

A second adapter device in accordance with the invention is preferably provided, wherein the second adapter device is arranged at an end of the section of the coaxial connection to be measured close with respect to the RFID reading device and the RFID reading device is configured to determine a transmission loss of the coaxial connection from measured values of the first adapter device and the second adapter device. The transmission loss can thus be determined for any desired RFID reading device whose transmission power is not known and that is also not necessarily adapted to the coaxial connection. The second adapter device can be the first adapter device that is again used with a time offset and that is released from its original position after a first measurement and is deployed in the coaxial connection at its new position. Two adapter devices are, however, preferably simultaneously deployed in the coaxial connection for a second measurement. The transmission loss between the two adapter devices is determined by the first and second adapter devices by a comparison of their two measured values. To determine the transmission loss of the whole coaxial connection, the adapter devices have to be directly connected to the second device or to the RFID reading device by the whole coaxial connection between the two adapter devices.

The first coaxial connector and the second coaxial connector of the least one first adapter device, in particular an adapter device in accordance with the invention, is releasably deployed in the coaxial connection for the method in accordance with the invention of measuring the signal power in a coaxial connection from an RFID reading device to a second device, in particular an antenna. The first adapter device is arranged at the remote end of the section of the coaxial connection to be measured, preferably directly at the second device, i.e. its second coaxial connector is directly connected to the second device. The RFID reading device starts a measurement of the signal power; the first adapter device thereupon determines the signal power of a signal of the RFID reading device propagating through the first adapter device and the RFID reading device then reads a measured value of the first adapter device. Evaluations and calculations can follow, either in the RFID reading device, for example by means of an app or script, or in a superior controller (middleware) that can be responsible for a plurality of RFID reading devices.

The communication between the RFID reading device and the at least one adapter device preferably takes place via a memory of the adapter device, in particular by communication by means of an RFID protocol. Both the RFID reading device and the first adapter device, in particular a measuring unit of the first adapter device, thus access the memory asynchronously. The communication of the RFID reading device preferably takes place via an RFID protocol. The memory can be equipped with an RFID circuit of an RFID transponder for this purpose.

The RFID reading device preferably starts a measurement of the at least first adapter device by storing a start signal in the memory, wherein the adapter device checks the memory for a start signal stored there and carries out a measurement of the signal power in the presence of a start signal. A more complex direct communication between the RFID reading device and the adapter device or its measuring unit is thus not required. The RFID reading device communicates its demands of a measurement by the start signal; the adapter device preferably checks for such a start signal cyclically and responds by carrying out a measurement. After the measurement, the corresponding measured value is available to the RFID reading device at any desired later time. The adapter device can store a time stamp or the like on the measured value.

The RFID reading device preferably generates a transmission signal of a known transmission power and in the process the first adapter device carries out a measurement of the signal power, wherein the RFID reading device determines a transmission loss of the coaxial connection from the known transmission power and from a measured value of the signal power determined by the first adapter device. The transmission signal can be a permanent signal or a modulate signal; the purpose of the transmitted signals is that a signal of the known transmission power is propagated by the first adapter device in good time for the measurement of the first adapter device and over its duration. The closing determination of the transmission loss results from the known transmission power and from the measured value of the signal line in the first adapter device at this known transmission power, in particular by difference formation.

A first measurement of the signal power is preferably carried out by the first adapter device while the RFID reading device generates a transmission signal and a second measurement of the signal power is additionally carried out by means of a second adapter device that is releasably deployed in the coaxial connection, in particular by means of a second adapter device in accordance with the invention, wherein the RFID reading device determines a transmission loss of the coaxial connection from a respective measured value of the two measurements. With this embodiment of the method, the transmission loss can be determined for any desired RFID reading devices with an unknown transmission power and without an adaptation of the RFID reading device to the coaxial connection. During the measurements, the RFID reading device is active at its unknown transmission power, for example by a continuous RFID query or a permanent inventory. The measurements are in particular started simultaneously or consecutively by a respective start signal written into the memory of the adapter devices. After measurements have taken place, the transmission loss is determined from the measured values of the two adapter devices, in particular by a difference formation. There are the alternatives already discussed in connection with the design possibilities of the device for the arrangement of the two adapter devices. The section of the coaxial connection to be measured is between the two adapter devices. The second adapter device can, likewise as already discussed, with two measurements offset in time, be the first adapter device arranged at a new position of the coaxial connection or a physical second adapter device that is deployed in the coaxial connection together with the first adapter device. What was stated on the first adapter device correspondingly applies to the properties and use of the second adapter device.

The RFID reading device preferably corrects a transmission loss of the coaxial connection by a known transmission loss of the at least first adapter device if the at least first adapter device does not remain in the coaxial connection in the further operation. The first adapter device and, if present, the second adapter device each generate their own transmission loss. This is, however, no longer relevant if an adapter device is only deployed temporarily and is removed from the coaxial connection again after a measurement has taken place. The transmission loss then drops accordingly. How high the correction has to be is a fixed parameter of the respective adapter device that the RFID reading device is aware of or that is in particular provided in the memory of the adapter device.

The invention will be explained in more detail in the following also with respect to further features and advantages by way of example with reference to embodiments and to the enclosed drawing. The Figures of the drawing show in:

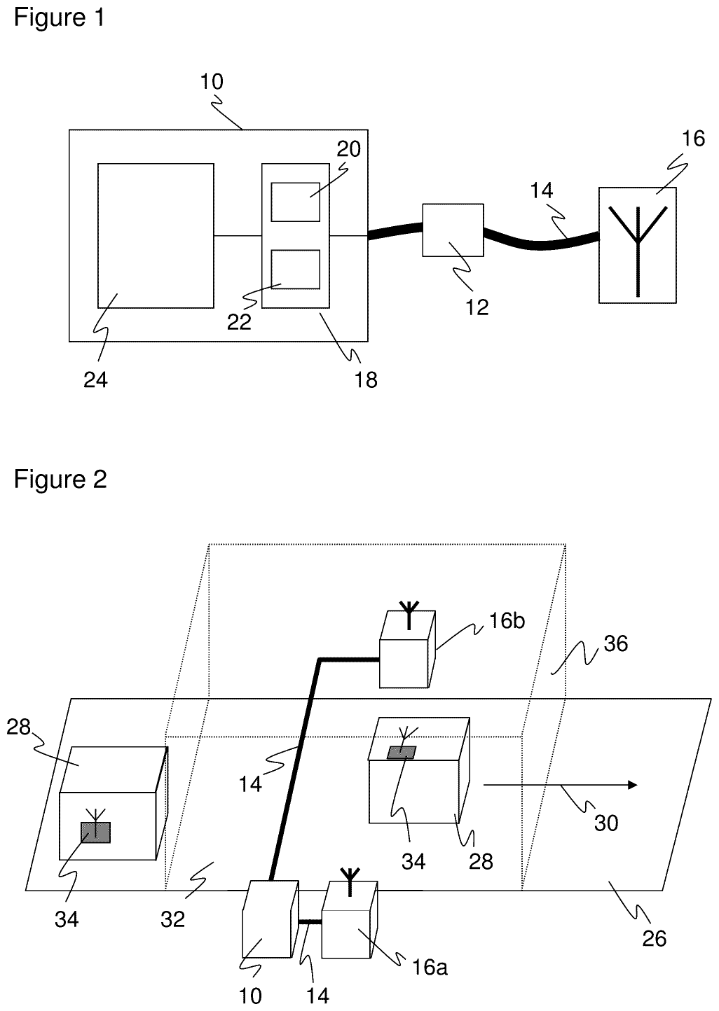

FIG. 1 a block diagram of an RFID reader with an adapted deployed in the coaxial connection to its antenna;

FIG. 2 a three-dimensional representation of the assembly of an RFID reader for an application at a conveyor belt;

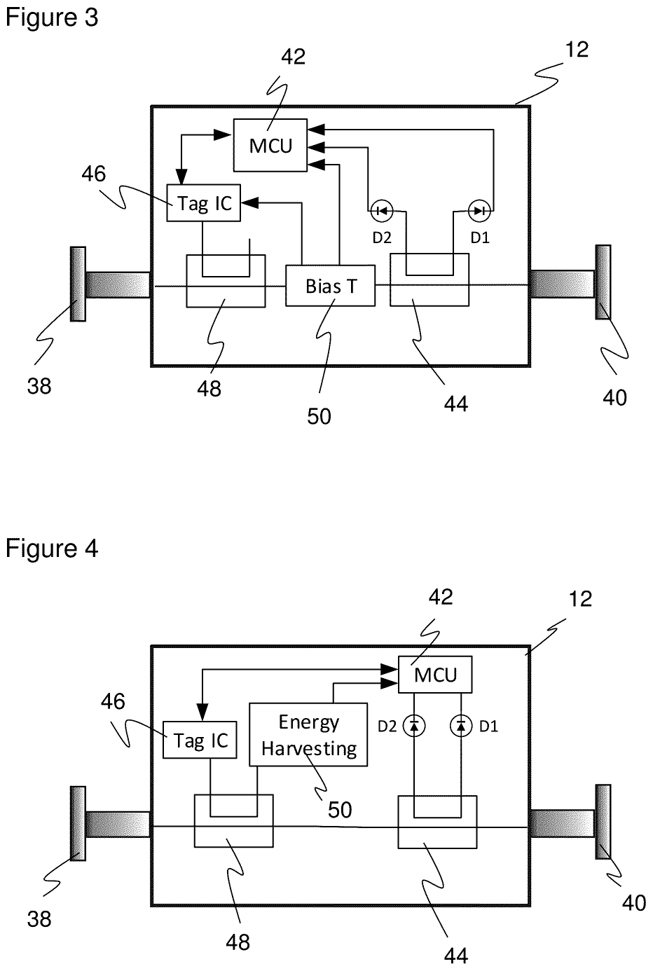

FIG. 3 a block diagram of an adapter;

FIG. 4 a block diagram of a further embodiment of an adapter;

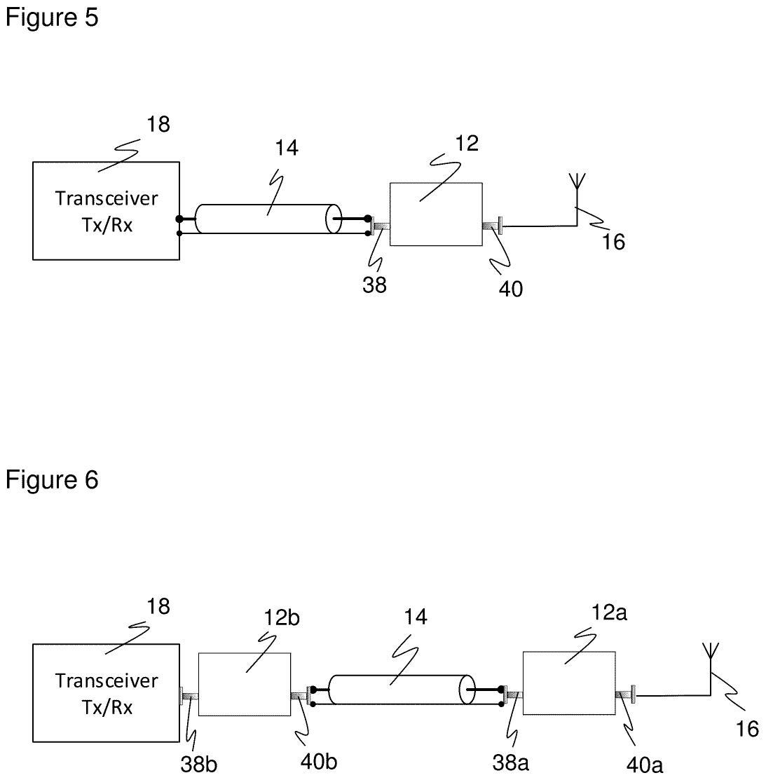

FIG. 5 a schematic representation of an arrangement of an adapter in a coaxial connection for the measurement of a transmission loss with a known transmitted power;

FIG. 6 a schematic representation of an arrangement of a second adapter in a coaxial connection for the measurement of a transmission loss with an unknown transmission power;

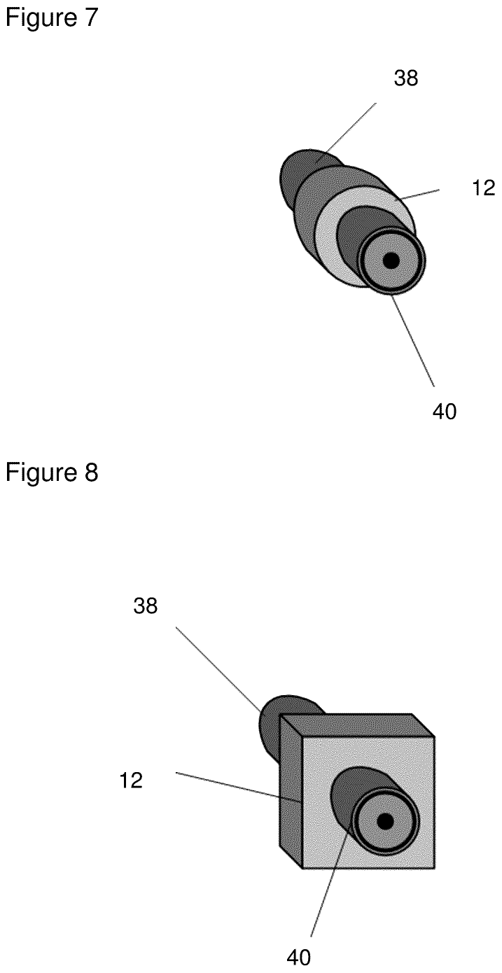

FIG. 7 a representation of an exemplary design of an adapter; and

FIG. 8 a representation of an alternative design of an adapter.

FIG. 1 shows a block diagram of an RFID reader 10 having an adapter 12 that is deployed in a coaxial connection 14 to an antenna 16 connected to the RFID reader 10. The adapter 12 is here only shown as a simple block and will be explained in more detail below with reference to FIGS. 3 to 6. The antenna 16 is representative for a second component connected to the RFID reader 10 by means of a coaxial connection 14.

The RFID reader 10 has a transmission/reception unit 18 having a transmitter 20 and a receiver 22 to receive RFID signals from the antenna 16 or to irradiate RFID signals over the antenna 16. The transmission/reception unit 18 can be configured as a transceiver.

A control and evaluation unit 24 is connected to the transmission/reception unit 18. It has at least a digital processing module such as a microprocessor or a CPU (central processing unit), an FPGA (field programmable gate array), a DSP (digital signal processor), an ASIC (application specific integrated circuit), an AI processor, an NPU (neural processing unit), a GPU (graphics processing unit) or the like. The control and evaluation unit 24 can be provided, differing from the illustration, at least in part externally, as a computer of any desired design, including notebooks, smartphones tables, as a controller, a local network, an edge device, a cloud, or another processing unit. The control and evaluation unit 24 receives an electronic signal corresponding to the received RFID signals from the receiver 22 or, via the transmitter 20, causes an RFID signal to be radiated. The control and evaluation unit 24 knows the RFID protocols to be used, for example in accordance with ISO 18000-6 or EPC Gen2, to encode information into an RFID signal or to read it from an RFID signal. RFID communication per se is known. The required components of the control and evaluation unit 24 and the steps required for RFID communication will therefore not be looked at in any more detail.

FIG. 2 additionally shows a three-dimensional representation of a typical application of the RFID reader 10 in a stationary installation at a conveyor belt 26. Objects 28 are conveyed on it through a reading zone 32 in a direction marked by an arrow 30. RFID transponders 34 are arranged at the objects 28 and are read by the RFID reader 10 when they are located in the reading zone 32.

A screen 36 is preferably provided above the reading zone that is only shown schematically and that protects both the RFID reader 10 against interference signals from the outside and the environment against the electromagnetic radiation of the RFID reader 10. The RFID reader 10 at the reading tunnel thus produced comprises, differing from the representation of FIG. 1, two antennas 16a-b. Further RFID readers or further antennas are conceivable, including internal antennas of the RFID reader 10 itself, to detect RFID signals at further positions and from further directions. Equally, other sensors are possibly provided to acquire additional information on the objects 28, for example their entry into and exit from the reading zone 32 or the volume or weight of the objects 28.

FIG. 3 shows a block diagram of an embodiment of the adapter 12. The adapter 12 has two coaxial connectors 38, 40, preferably of a type widespread for RFID applications such as R-TNC (threaded Neill Concelman reverse polarity). The adapter 12 can thus be deployed in the coaxial connection 14 in accordance with the very schematic representation of FIG. 1. There are various possibilities: The first coaxial connector 38 can be connected directly to the RFID reader 10 or to a coaxial cable connected thereto and the second coaxial connector 38 can be connected directly to the antenna 16 or to a coaxial cable connected thereto. In this respect, the coaxial connection 14 has only a single coaxial cable, a plurality of coaxial cables as part sections, wherein the coaxial connectors 38, 40 can be connected to the transitions of the coaxial cables, or has no coaxial cable at all in a direct connection of the RFID reader 10 and the antenna 16.

The adapter 12 comprises a measuring unit 42 for determining the signal power of a signal propagating through the adapter in the forward direction, the backward direction or in both directions. For this purpose, a signal decoupling 44 takes place over at least one of the diodes D1, D2. The measuring unit 42 is preferably configured to determine the maximum power of the transmitted signal, that is, for example, not a middle value, to preclude deviations of the measured signal power by the modulation of the transmission signal.

The adapter 12 preferably has at least one programmable memory 46 that can be addressed over a standardized protocol via a further coupling 48. The communication preferably takes place over an RFID protocol. The memory 46 can be equipped with corresponding circuits of an RFID transponder for this purpose. Alternatively, a different form of communication is conceivable, for example by modulated voltage as in the 1Wire protocol. However, the RFID reader 10 then has to understand this protocol while an RFID protocol is anyway implemented. A start signal for a measurement is preferably stored in the memory 46 by the RFID reader 10 and after a measurement has taken place by the measuring unit 42, the measured value for the signal power is stored, in addition, a value for the separate transmission damping of the adapter 12 can be stored there.

The adapter 12 moreover preferably has a circuit 50 for the energy supply from the signal transmitted on the coaxial connection 14 to avoid an alternatively conceivable separate energy source or battery. In the embodiment in accordance with FIG. 3, it is a supply by means of a phantom feed or a remote feed, for example by a bias T.

FIG. 4 shows a block diagram of a further embodiment of the adapter 12. Unlike FIG. 3, no phantom feed is required here. The circuit 50 for the energy supply has a rectifier or a charge pump to ensure the supply by means of energy harvesting. For this purpose, the circuit 50 has an energy store that is not shown separately such as a capacitor that is charged by the energy harvesting.

FIG. 5 shows a schematic representation of an arrangement of the adapter 12 in a coaxial connection 14 for the measurement of a transmission loss or the antenna adaptation with a known transmission power and an adapted RFID reader 10. A measurement is then sufficient with an adapter 12 that is preferably connected to the end of the coaxial connection facing the antenna 16. In a different arrangement, only the transmission loss of the section up to the adapter 12 is determined, which can be sensible, for example, in the case of a multipart coaxial connection.

An exemplary routine begins with the RFID reader 10 storing a start signal, in particular with a start time, in the memory 46 of the adapter 12. For this purpose, the transmission signal of the RFID reader 10 is switched on that thus accesses the memory 46. In the adapter 12, the measuring unit 42 queries the memory at regular intervals and therefore independently and synchronously recognizes the state change in the memory 46. It starts a measurement of the transmission power immediately, with a delay generally agreed in advance or at a time stormed with the start signal. The RFID reader 10 is correspondingly set at the latest since the storage of the start signal, with the agreed delay or at the stored time to its transmission power known, for example, by ex-works calibration and has switched on its transmission signal of this transmission power at least for the duration of the measurement. The measurement of the signal level therefore takes place at the known transmission power. The measuring unit 42 stores the signal power determined by it or the measured maximum signal level in the memory 46. The RFID reader 10 accesses the memory 46 to read the measured value. In this respect, a signal can be agreed by which the measuring unit 42 signals the end of the measurement, with this signal simply being able to comprise the measured value itself, unlike, for example, an empty memory position.

The possibly external control and evaluation unit 24 of the RFID reader 10 described as with respect to FIG. 1 determines the damping of the coaxial connection 14 or the transmission loss from the difference of the known transmission power and the measured value of the adapter 12. A query optionally finally takes place as to whether the adapter 12 remains in the coaxial connection 14 for the further operation. The transmission loss can be corrected by the separate transmission loss of the adapter 12, if the adapter 12 has now been dismantled, since this portion of the transmission loss disappears after the disassembly. The corresponding value can be parameterized in the RFID reader 10 or can be read from the memory 46. The adapter 12 can be used again at a different point by its removal. On the other hand, the remaining of the adapter for periodically repeated measurements with a check for changes is by all means a diagnostic advantage (predictive maintenance).

FIG. 6 shows a schematic representation of an arrangement of two adapters 12a-b in a coaxial connection 14 for the measurement of a transmission loss with an unknown transmission power and any desired not adapted or at most randomly adapted RFID reader 10. The two adapters 12a-b are preferably deployed at the two ends of the coaxial connection 14, that is at the antenna 16 and at the RFID reader 10. Otherwise, the transmission loss is not determined in the whole coaxial connection 14, but rather only in the partial portion between the adapters 12a-b. Alternatively to a common physical presence of two adapters 12a-b, it is conceivable to move the same adapter 12 successively to the two specified positions for a respective measurement.

An exemplary routine is largely similar to that that was described with reference to FIG. 5 so that only the differences will be looked at in more detail here. The start signal is now stored in both memories 46 of the adapters 12a-b. The measurements thereby triggered take place selectively simultaneously or consecutively. The respective measuring unit 42 of the adapters 12a-b queries its memory 46 at regular intervals and optionally starts its measurement at the associated time. The RFID reader 10 is set into a mode for continuous querying (permanent inventory) or provides that a signal is applied in a different manner. It is conceivable to have a phase with a switched on transmission signal precede the measurement in which a charge pump in accordance with FIG. 4 charges the energy store. The charge pump can then also be switched off in good time in order not to influence the measurement. Once both measurements have been carried out, the RFID reader reads the corresponding measured values of both adapters 12a-b. The damping or the transmission loss of the coaxial connection 14 results from the difference of the two measured values. Finally, a query can optionally take place as to whether the adapters 12a-b remain in the coaxial connection 14 or one of the adapters 12a-b remains to optionally correct by the transmission loss of an adapter 12a-b that has been removed again.

FIGS. 7 and 8 show two exemplary designs of the adapter 12 with largely universally usable coaxial connectors 38, 40. The adapter 12 takes up substantially the same installation space as a short section of the coaxial connection 14 and can be handled very simply and intuitively. The further routines preferably take place automatically; only a corresponding control program is required in the RFID reader 10 or in an external control and evaluation unit 24 of a superior processing unit. The invention has been described for the example of an RFID reader 10, but is equally usable for different transceivers or radio systems or coaxial connections 14 between components thereof.

1. An adapter device for measuring the signal power in a coaxial connection from an RFID reading device to a second device, wherein the adapter device has a first coaxial connector and a second coaxial connector for deploying the adapter device in the coaxial connection and a measuring unit that is configured to determine the signal power of a signal propagating from the first coaxial connector to the second coaxial connector and/or vice versa,
wherein the first coaxial connector and the second coaxial connector are releasable so that the adapter device can selectively be deployed in the coaxial connection or can be removed therefrom.

2. The adapter device in accordance with claim 1,
wherein the second device is an antenna.

3. The adapter device in accordance with claim 1,
wherein the measuring unit is configured to determine a maximum value of the signal power.

4. The adapter device in accordance with claim 1,
that has an energy supply unit by which the adapter device supplies itself from the signal that propagates on the coaxial connection.

5. The adapter device in accordance with claim 1,
that has a memory in which the measuring unit stores a measured value for the signal power.

6. The adapter device in accordance with claim 1,
wherein the memory is readable by means of an RFID protocol.

7. The adapter device in accordance with claim 6,
wherein the memory has an RFID transponder circuit.

8. The adapter device in accordance with claim 6,
wherein the measuring unit is configured to check the memory for a start signal stored there and to carry out a measurement of the signal power in the presence of a start signal.

9. An RFID reading device that has a second device and a coaxial connection to the second device and at least a first adapter device whose first coaxial connector and second coaxial connector are deployed in the coaxial connection, wherein the first adapter device is arranged at an end of the section of the coaxial connection to be measured remote with respect to the RFID reading device, wherein the first adapter device has the first coaxial connector and the second coaxial connector for deploying the adapter device in the coaxial connection and a measuring unit that is configured to determine the signal power of a signal propagating from the first coaxial connector to the second coaxial connector and/or vice versa,
wherein the first coaxial connector and the second coaxial connector are releasable so that the adapter device can selectively be deployed in the coaxial connection or can be removed therefrom.

10. The RFID reading device in accordance with claim 9, wherein the second device is an antenna.

11. The RFID reading device in accordance with claim 9,
wherein the transmission power of the RFID reading device is known in the RFID reading device and the RFID reading device is configured to determine a transmission loss of the coaxial connection from the known transmission power and from a measured value of the first adapter device.

12. The RFID reading device in accordance with claim 9,
that has a second adapter device, wherein the second adapter device is arranged at an end of the section of the coaxial connection to be measured close with respect to the RFID reading device and the RFID reading device is configured to determine a transmission loss of the coaxial connection from measured values of the first adapter device and the second adapter device,
wherein the second adapter device has a first coaxial connector and a second coaxial connector for deploying the adapter device in the coaxial connection and a measuring unit that is configured to determine the signal power of a signal propagating from the first coaxial connector to the second coaxial connector and/or vice versa,
wherein the first coaxial connector and the second coaxial connector are releasable so that the adapter device can selectively be deployed in the coaxial connection or can be removed therefrom.

13. A method of measuring the signal power in a coaxial connection from an RFID reading device to a second device, by means of at least a first adapter device whose first coaxial connector and whose second coaxial connector are releasably deployed in the coaxial connection, wherein the RFID reading device starts a measurement of the signal power, the first adapter device thereupon determines the signal power of a signal of the RFID reading device propagating through the first adapter device, and the RFID reading device then reads a measured value of the first adapter device.

14. The method in accordance with claim 13, wherein the second device is an antenna.

15. The method in accordance with claim 13, wherein the first adapter device has the first coaxial connector and the second coaxial connector for deploying the adapter device in the coaxial connection and a measuring unit that is configured to determine the signal power of a signal propagating from the first coaxial connector to the second coaxial connector and/or vice versa,
wherein the first coaxial connector and the second coaxial connector are releasable so that the adapter device can selectively be deployed in the coaxial connection or can be removed therefrom.

16. The method in accordance with claim 13,
wherein the communication between the RFID reading device and the at least first adapter device takes place over a memory of the adapter device.

17. The method in accordance with claim 13,
wherein the communication between the RFID reading device and the at least first adapter device takes place over a memory of the adapter device by communication by means of an RFID protocol.

18. The method in accordance with claim 13,
wherein the RFID reading device starts a measurement of the at least first adapter device by storing a start signal in the memory, and wherein the adapter device checks the memory for a start signal stored there and carries out a measurement of the signal line in the presence of a start signal.

19. The method in accordance with claim 13,
wherein the RFID reading device generates a transmission signal of a known transmission power and in the process the first adapter device carries out a measurement of the signal power, and wherein the RFID reading device determines a transmission loss of the coaxial connection from the known transmission power and from a measured value of the signal power determined by the first adapter device.

20. The method in accordance with claim 13,
wherein a first measurement of the signal power is carried out by the first adapter device while the RFID reading device generates a transmission signal and a second measurement of the signal power is additionally carried out by a second adapter device that is releasably deployed in the coaxial cable connection, and wherein the RFID reading device determines a transmission loss of the coaxial connection from a respective measured value of the two measurements.

21. The method in accordance with claim 13, wherein the second adapter device has a first coaxial connector and a second coaxial connector for deploying the adapter device in the coaxial connection and a measuring unit that is configured to determine the signal power of a signal propagating from the first coaxial connector to the second coaxial connector and/or vice versa,
wherein the first coaxial connector and the second coaxial connector are releasable so that the adapter device can selectively be deployed in the coaxial connection or can be removed therefrom

22. The method in accordance with claim 13,
wherein the RFID reading device corrects a transmission loss of the coaxial connection by a known transmission loss of the at least first adapter device if the at least first adapter device does not remain in the coaxial connection in the further operation.
